(19) United States
(12) Patent Application Publication
(10) Pub. No.: US 2024/0215228 A1
(43) Pub. Date: Jun. 27, 2024

(54) SEMICONDUCTOR INTEGRATED CIRCUIT DEVICE INCLUDING A WORD LINE WITH VARIABLE WIDTHS

(71) Applicant: SK hynix Inc., Gyeonggi-do (KR)

(72) Inventor: Seok Young KANG, Gyeonggi-do (KR)

(21) Appl. No.: 18/353,110

(22) Filed: Jul. 17, 2023

(30) Foreign Application Priority Data
Dec. 22, 2022 (KR) 10-2022-0181643

(51) Int. Cl. H10B 12/00

(52) U.S. Cl. CPC H10B 12/488; H10B 12/34

(57) ABSTRACT

A semiconductor integrated circuit device includes a semiconductor substrate, an active region and a word line. The active region is defined by an isolation region formed in the semiconductor substrate. The active region includes at least one contact region. The word line includes a main gate and a pass gate. The main gate is arranged in the active region. The pass gate is positioned away from the main gate. The pass gate is positioned in the isolation region. The contact region is arranged at one side of the main gate. A sidewall of the main gate includes a first recessed portion configured to surround the contact region. The first recessed portion may be spaced apart from the contact region by a first distance.

### CROSS-REFERENCES TO RELATED APPLICATION

The present application claims priority under 35 U.S.C. § 119(a) to Korean application number 10-2022-0181643, filed on Dec. 22, 2022, in the Korean Intellectual Property Office, which is incorporated herein by reference in its entirety.

### BACKGROUND

### 1. Technical Field

Various of the disclosed embodiments generally relate to a semiconductor integrated circuit device, more particularly, to a semiconductor integrated circuit device having a word line with variable widths to improve a row hammer characteristic.

### 2. Related Art

A semiconductor memory device may include a plurality of word lines, a plurality of bit lines and a storage element connected between the word lines and the bit lines.

As semiconductor memory devices have become highly integrated, a pitch between the word lines has become narrower which generates more coupling between word lines.

Further, as a toggling number of the word line (or frequency of word line access) has increased, data in the storage device (connected with an adjacent word line) may be coupled to a corresponding word line which can generate a row hammer effect. The row hammer effect often causes a loss of the data from the storage element which decreases a refresh characteristic of the storage element.

### SUMMARY

According to the disclosed embodiments presented here, there is provided a semiconductor integrated circuit device which includes a semiconductor substrate, an active region and a word line. The active region is defined by an isolation region formed in the semiconductor substrate. The active region includes at least one contact region. The word line includes a main gate and a pass gate. The main gate is arranged in the active region. The pass gate is positioned away from the main gate. The pass gate is positioned in the isolation region. The contact region is arranged at one side of the main gate. A sidewall of the main gate includes a first recessed portion configured to surround the contact region. The first recessed portion may be spaced apart from the contact region by a first distance.

In various embodiments, the contact region may include a storage node contact.

In various embodiments, the first distance may be a maximum distance for inducing a charge coupling with insulation maintenance between the word line and the contact region.

In various embodiments, the contact region in the active region may include a plurality of contact regions. Any one of the contact regions may be a storage node contact positioned at a first side of the main gate. The other one of the contact regions may be a bit line contact positioned at the other side of the main gate.

According to the disclosed embodiments, there is provided another semiconductor integrated circuit device which includes a plurality of active regions a plurality of word lines. The active regions are defined by an isolation region. Each of the active regions includes portions configured to make contact with a storage node contact and a bit line contact. Each of the word lines includes a plurality of first gates and a plurality of second gates. The first gates pass between the storage node contact and the bit line contact in the active regions. The second gates are extended from the main gates to pass through the isolation region. The first gate includes a first recessed portion and a second recessed portion. The first recessed portion is positioned at a first sidewall of the first gate adjacent to the storage node contact. The second recessed portion is positioned at a second sidewall of the first gate adjacent to the bit line contact.

According to the disclosed embodiments, there is provided another semiconductor integrated circuit device which includes a plurality of active regions and a plurality of word lines. The word lines are parallelly extended on an isolation region which is configured to define the active regions. Each of the word lines includes a main gate passing through the active regions and a pass gate passing through the isolation region. A width of the main gate and a width of a first portion in the pass gate are narrower than a width of the word line. A second portion extended from the first portion of the pass gate is substantially the same as the width of the word line.

According to various embodiments, the word line may have a recessed gate structure to prevent charge coupling at an interface between the word lines from being generated. Further, any remaining charge may be transmitted to an adjacent storage capacitor to improve a row hammer characteristic.

### BRIEF DESCRIPTION OF THE DRAWINGS

The above and another aspects, features and advantages of the subject matter of the present disclosure will be more clearly understood from the following detailed description taken in conjunction with the accompanying drawings, in which:

FIG. 1 is a plan view illustrating a semiconductor integrated circuit device in accordance with various embodiments;

FIG. 2 is an enlarged perspective view of a portion “A” in FIG. 1;

FIG. 3 is a plan view illustrating a semiconductor integrated circuit device in accordance with other embodiments;

FIG. 4 is an enlarged perspective view of a portion “B” in FIG. 3;

FIGS. 5A to 7A are plan views illustrating a method of manufacturing a semiconductor integrated circuit device in accordance with still other embodiments;

FIGS. 5B to 7B are cross-sectional views taken along lines b-b′ in FIGS. 5A to 7A;

FIG. 8 is a perspective view illustrating a semiconductor integrated circuit device with a storage node contact in accordance with yet other embodiments;

FIG. 9 is a plan view illustrating a semiconductor integrated circuit device in accordance with further embodiments; and

FIG. 10 is a plan view illustrating a semiconductor integrated circuit device in accordance with other embodiments.

### DETAILED DESCRIPTION

Various embodiments of the present invention will be described in greater detail with reference to the accompanying drawings. The drawings are schematic illustrations of various embodiments (and intermediate structures). As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the scope of the present invention.

The present invention is described herein with reference to cross-section and/or plan illustrations of idealized embodiments of the present invention. However, embodiments of the present invention should not be construed as limiting the inventive concept. Although a few embodiments of the present invention will be shown and described, it will be appreciated by those of ordinary skill in the art that changes may be made in these embodiments without departing from the principles of the present invention.

Hereinafter, the disclosed embodiments are explained in detail with reference to the accompanying drawings.

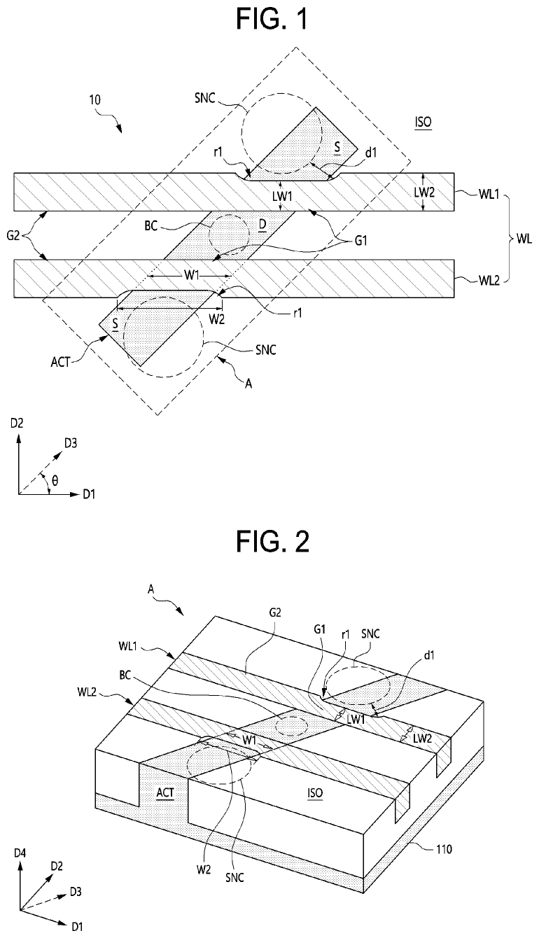

FIG. 1 is a plan view illustrating a semiconductor integrated circuit device in accordance with various embodiments and FIG. 2 is an enlarged perspective view showing a portion “A” from FIG. 1.

Hereinafter, a first direction D1 (for example, horizontal direction), a second direction D2 (for example, vertical direction) and a third direction D3 (for example, diagonal direction) may be positioned on a same plane. The first direction D1 and the second direction D2 may be substantially perpendicular to each other. The third direction D3 may be inclined to the first and second directions D1 and D2 by an acute angle θ. For example, the third direction D3 may be a diagonal direction. Further, a fourth direction D4 in FIG. 2 may be a vertical direction or a stacking direction intersected with the first to third directions D1, D2 and D3.

A semiconductor integrated circuit device of the various embodiments disclosed here may be a dynamic random access memory (DRAM). The first direction D1 may be an extending direction of a word line in the DRAM. The second direction D2 may be an extending direction of a bit line in the DRAM.

Referring to FIGS. 1 and 2, the semiconductor integrated circuit device 10 may include a semiconductor substrate 110 and a plurality of word lines. The semiconductor substrate 110 may include an isolation region ISO and an active region ACT.

The semiconductor substrate 110 may include for example a silicon substrate, a silicon-germanium (Si—Ge) substrate, a silicon-on-insulation (SOI) substrate, etc. The semiconductor substrate 110 may include first type impurities, for example, P type impurities. The semiconductor substrate 110 may include a conductive well having the first type impurities.

The isolation region ISO may be formed in the semiconductor substrate 110 to have a shallow trench isolation (STI) structure. The active region ACT may correspond to a portion of the semiconductor substrate 110 without the isolation region ISO. A planar structure of the active region ACT may have a bar structure extended in the third direction D3.

The word lines (e.g., WL1 and WL2) may extend parallel with the first direction D1. In one example, the word lines may be slanted to the active region ACT by an acute angle. The two word lines by the active region ACT may be overlapped with each other. In various embodiments disclosed here, the word lines may include a first word line WL1 and a second word line WL2. Each of the first and second word lines WL1 and WL2 may be positioned in the active region ACT and/or the isolation region ISO. A portion of the word lines WL1 and WL2 in the active region ACT may be operated as a first gate, for example, a main gate G1 for gating of a channel in the active region an access transistor in a memory cell. A portion of the word lines WL1 and WL2 in the isolation region ISO may be operated as a second gate, for example, a pass gate G2 configured to transmit a word line signal. Thus, each of the word lines WL1 and WL2 may include the main gate G1 and the pass gate G2.

Regions where a source S and a drain D may be to be formed may be defined in the active region ACT by the main gate G1. The source S and the drain D may form the access transistor of the memory cell together with the main gate G1. The source S and the drain D may be a junction region including second type impurities opposite to the first conductive type.

In other embodiments, the source S may be formed at the active region ACT outside the main gates G1. The source S may make contact with a storage node capacitor or a storage node contact SNC. The drain D may be formed in the active region ACT between the main gates G1. The drain D may make contact with a bit line (not shown) or a bit line contact BC electrically connected to the bit line.

In other embodiments, at least one of the storage node contact SNC and the bit line contact BC may be expanded to the isolation region ISO as well as the source S and the drain D to secure a sufficient contact area.

In other embodiments, the main gate G1 may include a first recessed portion r1 to maintain a first distance d1 between the main gate G1 and the storage node contact SNC. The first recessed portion r1 may be positioned at a sidewall of the main gate G1 facing the storage node contact SNC (hereinafter, referred to as a first sidewall). The first distance d1 may be a maximum distance for inducing charge coupling with a maintenance of an insulation between two objects, for example, the main gate G1 and the storage node contact SNC remain insulated from each other without electrically being shorted together. An insulation layer may be interposed between the main gate G1 and the storage node contact SNC.

The first recessed portion r1 may have a width W2 greater than a width W1 of the main gate G1. For example, the term “width” may be understood as “linewidth”. Thus, an area of the main gate G1 facing the storage node contact SNC may be increased by the first recessed portion r1 within a range of the first distance d1.

In one embodiment, when the first word line WL1 is selected, charges of the storage node contact SNC adjacent to the main gate G1 of the first word line WL1 may be trapped. In contrast, in another embodiment, when the first word line WL is not selected, a homing ratio of the trapped charges, that is a ratio of a) trapped charges on a gate returned to the adjacent storage node contact SNC to b) charges on the gate not returned, may be increased due to the enlarged area (and resulting higher capacitance) of the main gate G1 in the first word line WL1 facing the storage node contact SNC within the first distance d1 by the first recessed portion r1, thereby improving a row hammer characteristic by reducing the amount of trapped charge particularly on a non-selected gate.

Further, because the first recessed portion r1 may be provided to the sidewall of the main gate G1, the width LW1 of the main gate G1 may be narrower than the width LW2 of the main gate G1.

In various embodiments disclosed here, a size of the storage node contact SNC may be magnified with respect to the bit line contact BC for conveniences of explanations. Thus, the size of the storage node contact SNC may not be restricted to the relative sizes in the drawings.

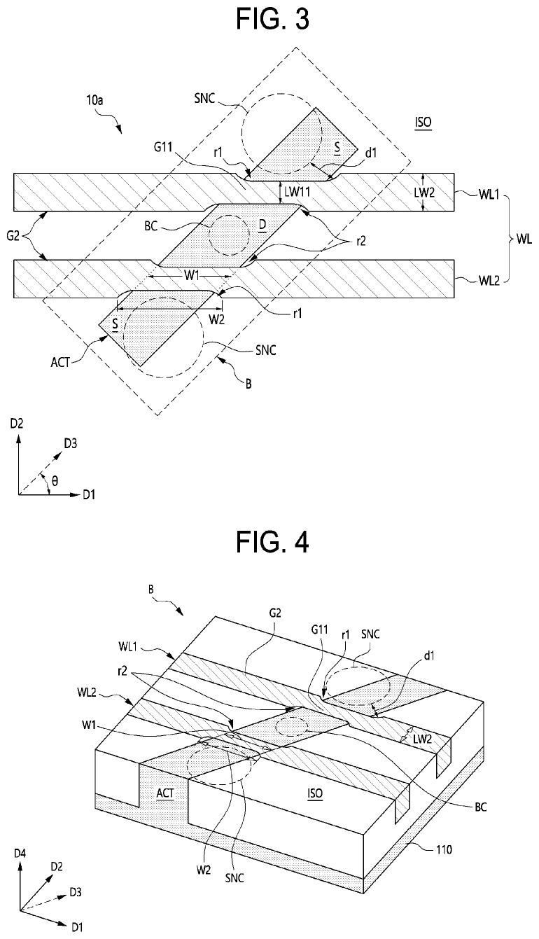

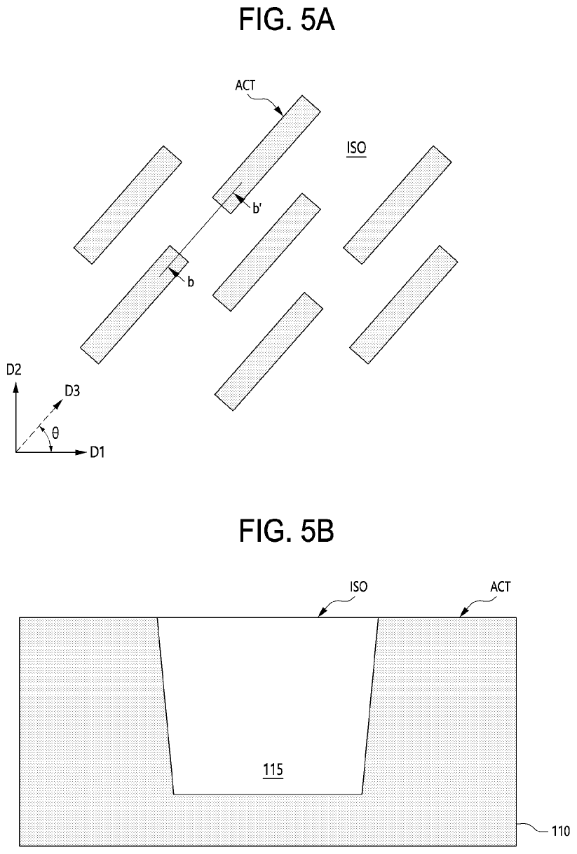

FIG. 3 is a plan view illustrating a semiconductor integrated circuit device in accordance with still other embodiments and FIG. 4 is an enlarged perspective view showing a portion “B” from FIG. 3.

A semiconductor integrated circuit device 10a shown in FIG. 3 may have a structure substantially the same as the structure of the semiconductor integrated circuit device 10 in FIGS. 1 and 2 except for the structure of a main gate G11.

Referring to FIGS. 3 and 4, the main gate G11 may further include a second recessed portion r2 as well as the first recessed portion r1. In order to maintain a second distance d2 between the main gate G11 and the bit line contact BC, the second recessed portion r2 may be formed at a sidewall of the main gate G11 facing the bit line contact BC (hereinafter, referred to as a second sidewall). The second distance d2 may be substantially equal to or different from the first distance d1.

In various embodiments disclosed here, the second recessed portion r2 may be symmetrical with the first recessed portion r1. The second sidewall of the main gate G11 may be spaced apart from the bit line contact BC by the second distance d2 due to the second recessed portion r2. The bit line contact BC may not be surrounded by the second recessed portion r2.

Further, by the formation of the first and second recessed portions r1 and r2, a width LW11 of the main gate G11 may be narrower than the width LW2 of the pass gate G2.

As mentioned above, the first recessed portion r1 may be formed at the main gate G11 so that the charges trapped in the non-selected main gate G2 may be readily returned to the adjacent storage node contact SNC to improve (reduce) the row hammer characteristic.

Further, the second recessed portion r2 may be simultaneously formed with the first recessed portion r1. The second recessed portion r2 may be symmetrical with the first recessed portion r1. Thus, a fabrication process may be decreased compared to a process for selectively forming the first recessed portion r1.

Hereinafter, a method of manufacturing the semiconductor integrated circuit device in FIGS. 3 and 4 may be illustrated in detail.

FIGS. 5A to 7A are plan views illustrating a method of manufacturing a semiconductor integrated circuit device in accordance with various embodiments disclosed here and FIGS. 5B to 7B are cross-sectional views taken along lines b-b′ in FIGS. 5A to 7A.

Referring to FIGS. 5A and 5B, a mask pattern for defining active region may be formed on a semiconductor substrate. For example, the semiconductor substrate 110 may include a silicon material having the first type impurities. The semiconductor substrate 110 may be etched using the mask pattern as an etch mask to form a trench. The trench may be filled with an insulation material 115 to form the isolation region ISO. In example embodiments, the insulation material 115 may include a silicon oxide layer, but the present disclosure is not limited thereto. For example, the insulation material 115 may include a plurality of dielectric layers.

The isolation region ISO may define a plurality of the active regions ACT in the semiconductor substrate 110. Each of the active regions ACT may have the bar shape extended in the third direction D3. The active regions ACT may be uniformly arranged to integrate multiple memory cells into one area.

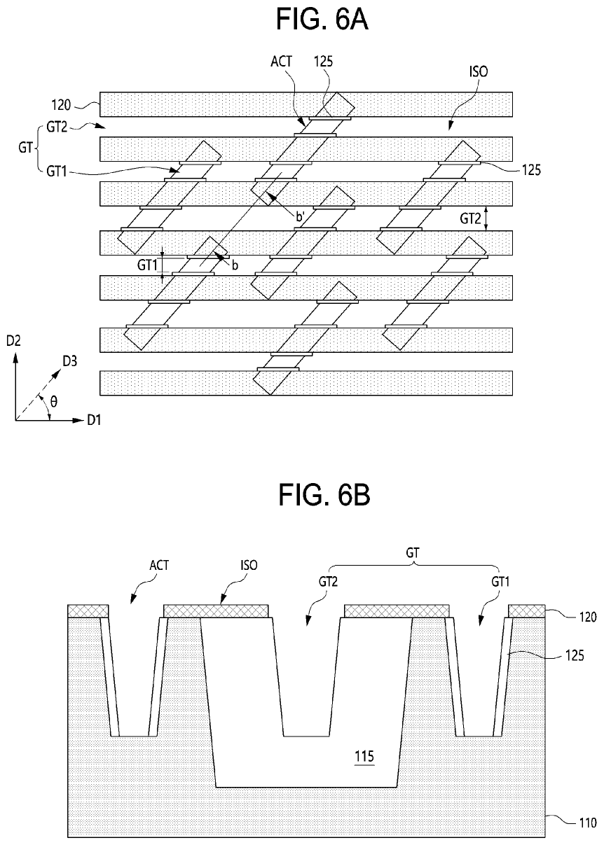

Referring to FIGS. 6A and 6B, a mask pattern 120 for defining a word line may be formed on the semiconductor substrate 110 with the active region ACT. The mask pattern 120 may be configured to expose a region where the word line may be formed. The mask pattern 120 may include a silicon nitride layer, but the present disclosure is not limited thereto. The mask pattern 120 may not be etched when etching the semiconductor substrate 110 and the insulation material 115.

The active region ACT and the isolation region ISO exposed through the mask pattern 120 may be etched to form a gate trench GT, as shown in FIG. 6B. The gate trench GT may include a first gate trench GT1 in the active region ACT and a second gate trench GT2 in the isolation region ISO. The silicon in the semiconductor substrate may be exposed through the first gate trench GT1. The insulation material 115 in the isolation region ISO may be exposed through the second gate trench GT2.

An exposed sidewall of the first gate trench GT1 may be partially oxidized using a difference between an etching selectivity of the silicon and an etching selectivity of the insulation material 115 exposed through the first and second gate trenches GT1 and GT2 to form an oxide layer. The oxide layer on a bottom surface of the first gate trench GT1 may be selectively removed to form a sidewall oxide layer 125.

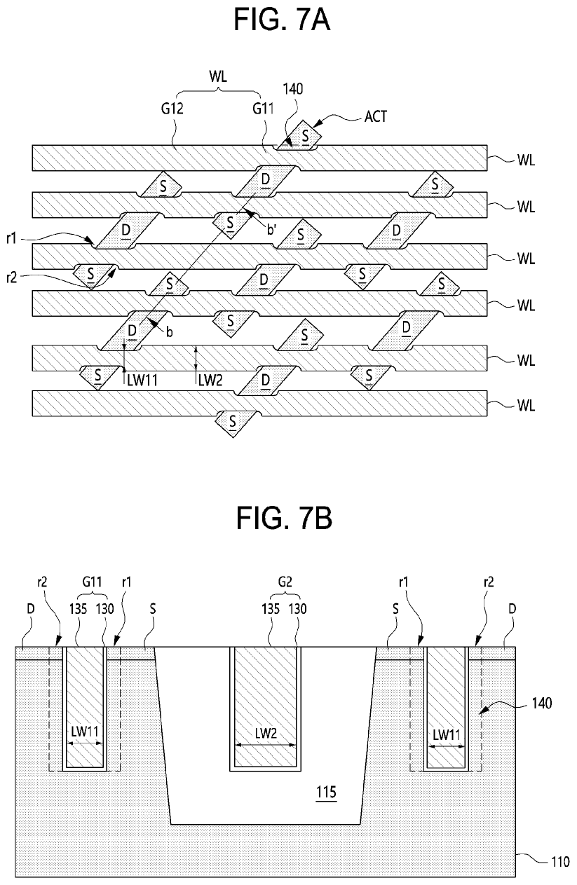

Referring to FIGS. 7A and 7B, the sidewall oxide layer 125 may be removed to expose a sidewall of the first gate trench GT1. An epitaxial layer 140 may be formed in the sidewall of the first gate trench GT1 using a SEG (selective epitaxial growth). Thus, a width of the first gate trench GT1 may be reduced by the epitaxial layer 140.

The mask pattern 120 may be removed, and then a gate insulation layer 130 may be formed along surfaces of the first gate trench GT1. The first and second gate trenches GT1 and GT2 may be filled with a gate conductive layer 135, to form the word line WL. The gate conductive layer 135 may include at least one or more of polycrystalline silicon (Si), titanium (Ti), titanium nitride (TiN), tantalum (Ta), tantalum nitride (TaN), tungsten (W), tungsten nitride (WN) and aluminum (Al). In other embodiments, the word line WL may include a plurality of stacked layers. Thus, the word lines WL including the main gate G11 and the pass gate G2 may be formed. For example, the main gate G11 may be formed in the first gate trench GT1 and the pass gate G12 may be formed in the second gate trench GT2. A width of the main gate G11 may be narrower than that of the pass gate G12 by the epitaxial layer 140. In other embodiments, the gate trench GT may be fully filled with the gate conductive layer 135, but the present disclosure is not limited thereto. Alternatively, a lower region in the gate trench GT may be filled with the gate conductive layer 135. An upper region in the gate trench GT may be filled with a buried insulation layer (not shown). Further, the gate insulation layer 130 may include a nitride liner and a silicon oxide layer stacked on the nitride liner.

In various embodiments disclosed here, the sidewall oxide layer 125 may be selectively removed between the formations of the nitride liner and the silicon oxide layer. Further, in one embodiment, an epitaxial layer 140 may be formed in a space formed by the removal of the sidewall oxide layer 125 between the formations of the nitride liner and the silicon oxide layer. In on embodiment, a sidewall of the first gate trench GT1 may be selectively grown to form the epitaxial layer 140, without forming the sidewall oxide layer 125.

In one embodiment, since both sidewalls of the main gate G11 are recessed compared to both sidewalls of the pass gate G12, one sidewall of the main gate G11 will be referred a first recessed portion r1 and the other sidewall of the main gate G11 will be referred a second recessed portion r2. Because the epitaxial layer 140 may grow from the silicon in the active region ACT, the epitaxial layer 140 may be operated as the active region ACT.

In other embodiments, the first and second recessed portions r1 and r2 may be formed without a mask using the etching selectivity difference between the exposed materials, but the present disclosure is not limited thereto. The word lines with the first and second recessed portions r1 and r2 may be formed by various processes.

By forming the first and second recessed portions r1 and r2, the width LW11 of the main gate G11 in the word lines WL may be narrower than the width LW12 of the pass gate G12. The width LW11 of the main gate G11 may be partially decreased by the first and second recessed portions r1 and r2 so that a total resistance of the word line may not be significantly influenced by the narrow width LW11 of the main gate G11.

The second conductive type impurities opposite to the first conductive type may be implanted into the active regions ACT at both sides of the word line WL to form the source S and the drain D.

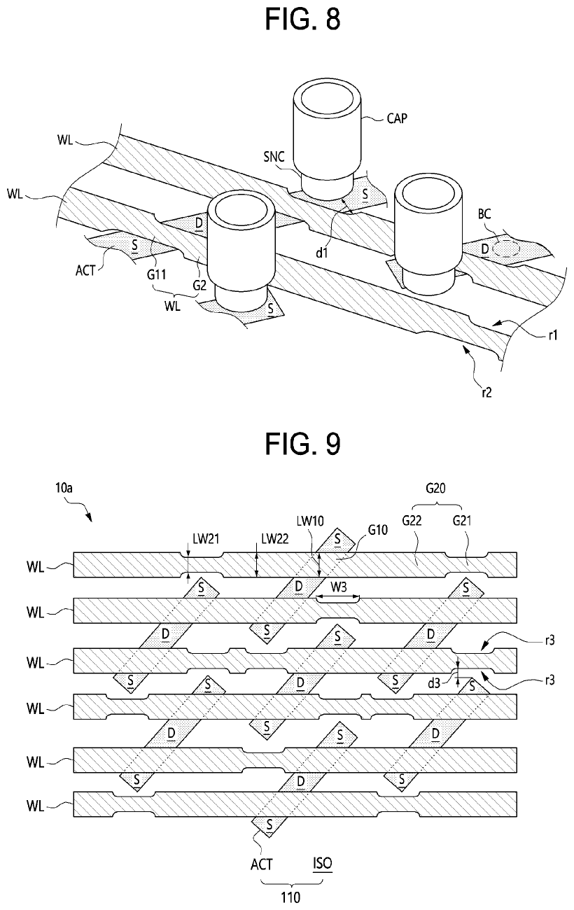

FIG. 8 is a perspective view illustrating a semiconductor integrated circuit device with a storage node contact in accordance with various embodiments disclosed here.

A storage node contact SNC in FIG. 8 may be formed on the source S. For example, the storage node contact SNC may have a plug structure. A bit line contact BC may be formed on the drain D. The bit line contact BC may have a height different from a height of the storage node contact SNC. A storage node capacitor CAP may be formed on the storage node contact SNC.

As mentioned above, in order to secure the contact area of the storage node contact SNC, the storage node contact SNC may occupy the source S and a part of the isolation region IOS adjacent to the source S.

Further, the main gate G1 may partially surround the storage node contact SNC within the first distance d1 along the horizontal, vertical and diagonal directions by the first recessed portion r1. Thus, the charges trapped in the non-selected main gate G1 may be readily returned to the storage node contact SNC.

FIG. 9 is a plan view illustrating a semiconductor integrated circuit device in accordance with other embodiments.

Referring to FIG. 9, a semiconductor integrated circuit device 10a may include a semiconductor substrate 110 and a plurality of word lines WL. The semiconductor substrate 110 may include at least one active region ACT and an isolation region ISO. The word lines WL may be arranged on the active region ACT and the isolation region ISO.

Each of the word lines WL may include at least one main gate G10 and at least one pass gate G20.

The main gate G10 may have a width LW10 without a recessed portion.

The pass gate G20 may include a first portion G21 and a second portion G22.

The first portion G21 may include at least one sidewall facing an edge portion of the active region ACT, for example, the source S in which the storage node contact SNC may be positioned.

A third recessed portion r3 may be formed on at least one of the both sidewalls of the first portion G21, particularly, a sidewall facing the source S of the active region ACT. The third recessed portion r3 may function as to secure a gap between the pass gate G20 and the storage node contact, thereby preventing the generation of the charge coupling differently from how the first recessed portion r1 prevents charge coupling. For example, a depth of the third recessed portion r3 of the pass gate G20 may be set to prevent the generation of the charge coupling between the pass gate G20 and the source S or between the pass gate G20 and the storage node contact connected to the source S.

The third recessed portion r3 may be spaced apart from the source S of the active region ACT, particularly, the storage node contact SNC, to prevent charge coupling.

Therefore, the first portion G21 of the pass gate G20 may have a width LW21 narrower than the width LW10 of the main gate G10.

The second portion G22 may be positioned between the isolation regions ISO. The second portion G22 may not face the active region ACT. The second portion G22 of the pass gate G20 may have a width LW22 substantially the same as the width LW10 of the main gate G10.

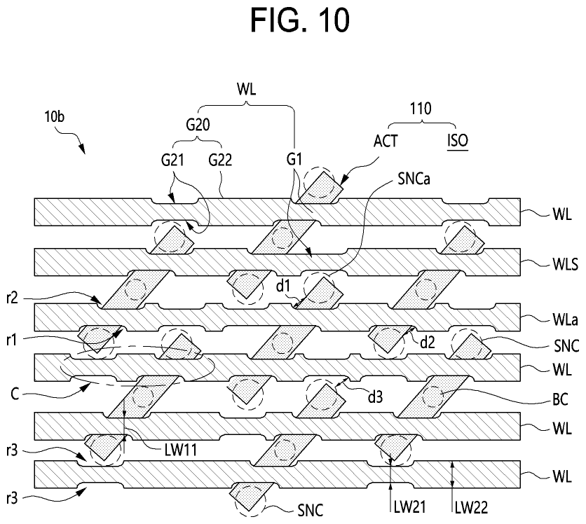

FIG. 10 is a plan view illustrating a semiconductor integrated circuit device in accordance with other embodiments.

Referring to FIG. 10, a semiconductor integrated circuit device 10b may include a semiconductor substrate 110 and a plurality of word lines WL. The semiconductor substrate 110 may include an active region ACT and an isolation region ISO. The word lines WL may be arranged on the semiconductor substrate 110.

Each of the word lines WL may include a main gate G1 and a pass gate G20.

As shown in FIGS. 1, 3 and 10, the main gate G1 may include the first recessed portion r1 and/or the second recessed portion r2 to surround the storage node contact SNC and/or the bit line contact BC. In further embodiments, the main gate G1 may include the first and second recessed portions r1 and r2. The width LW11 of the main gate G1 may be narrower than the width of the word line by the first and second recessed portions r1 and r2. The main gate G1 and the storage node contact SNC dependent upon the operation of the main gate G1 may have an increased overlapped region with the maintenance of the gap for inducing the charge coupling. The main gate G1 and the bit line contact BC dependent upon the operation of the main gate G1 may be spaced apart from each other by a gap for preventing the charge coupling due to the second recessed portion r2.

As shown in FIGS. 9 and 10, the pass gate G20 may include the first portion G21 and the second portion G22. The third recessed portion r3 may be formed at the first portion G21 of the pass gate G20, i.e., the sidewall of the pass gate G20 facing the source S of the adjacent active region ACT irrelevant to the operation of the pass gate G20.

As mentioned above, the main gate G1 may be spaced apart from the storage node contact SNC making contact with the source S along the first to third directions D1, D2 and D3 by the first distance d1 due to the first recessed portion r1. The first distance d1 may be a maximum distance for inducing charge coupling.

The main gate G1 may be spaced apart from the bit line contact BC making contact with the drain D by the second distance D2 due to the second recessed portion r2. The second distance d2 may be a minimum distance for preventing the charge coupling.

The pass gate G20 may be spaced apart from the storage node contact SNC of the adjacent active region ACT by the third distance d3 due to the third recessed portion r3. The third distance d3 may be the minimum distance for preventing the charge coupling.

As shown in a portion “C” in FIG. 10, as an integration degree of the active region ACT may have been increased, the first recessed portion r1 and the third recess portion r3 may be disposed next to each other on one side surface of the word line WL. The second recessed portion r2 with the third recessed portion r3 may be disposed next to each other on the other side surface of the word line WL.

In other embodiments, when the active region ACT, the storage node contact SNC and the bit line contact BC may be formed in a uniform pattern, the first to third recessed portions r1, r2 and r3 on the word line WL may have a uniform gap. Thus, the word line WL including the main gate G1 and the pass gate G20 may have a uniformly repeated width.

In still other embodiments, the word line WL may have the set width LW22 and the decreased with LW1 and LW21 alternately arranged to have an uneven structure.

As shown in FIG. 10, a distance d1 between a main gate G1 of a selected word line WLs and an adjacent storage node contact SNCa operated by an adjacent word line WLa may be secured. Thus, when the selected word line WLs is disabled, charges trapped in the main gate G1 of the selected word line WLs may be returned to the adjacent storage node contact SNCa. Thus, in one embodiment, when the word line is not selected, charges coupled to the main gate G1 may be returned to the storage node contact SNC.

The main gate G1 and the bit line contact BC, which may transmit data based upon the main gate G1, adjacent to the word line WL may be spaced apart from each other due to the second recessed portion r2 so that the charge coupling may not be induced, which will decrease an off-current.

Further, the pass gate G22 and the storage node contact SNC adjacent to the pass gate G22 in the word line WL may be spaced apart from each other due to the third recessed portion r3 so that the charge coupling may not be induced, which will decrease the off-current.

According to further embodiments, the word line may have the recessed structures to prevent remaining charges at an interface between the word lines from being generated. Further, the remaining charges may be transmitted to an adjacent storage capacitor, which will improve the row hammer characteristic.

Further, the recessed portion may be formed at the word line using the etching selectivity difference of the materials in the substrate where the word line may be formed, but the present disclosure is not limited thereto.

The word line may include the buried type, but the present disclosure is not limited thereto. For example, a structure having a pattern on the semiconductor substrate may also be applied to example embodiments.

The above described embodiments of the present invention are intended to illustrate and not to limit the present invention. Various alternatives and equivalents are possible. The invention is not limited by the embodiments described herein. Nor is the invention limited to any specific type of semiconductor device. Another additions, subtractions, or modifications are readily apparent in view of the present disclosure and are intended to fall within the scope of the present disclosure.

What is claimed is:

1. A semiconductor integrated circuit device comprising:
a semiconductor substrate;
an isolation region;
an active region defined by the isolation region in the semiconductor substrate, the active region including at least one contact region; and
a word line including a main gate and a pass gate, the main gate formed on the active region and the pass gate positioned away from the main gate and positioned in the isolation region,
wherein the contact region is positioned at one side of the main gate, and sidewalls of the main gate comprises a first recessed portion configured to surround the contact region while maintain a first distance between the sidewall of the main gate and the contact region.

2. The semiconductor integrated circuit device of claim 1, wherein the contact region comprises a storage node contact.

3. The semiconductor integrated circuit device of claim 1, wherein the first distance is a maximum distance for inducing charge coupling between the word line and the contact region.

4. The semiconductor integrated circuit device of claim 1, wherein the contact region in the active region comprises a plurality of regions, one of the contact regions is a storage node contact at a first side of the main gate and another of the contact regions is a bit line contact at a second side of the main gate.

5. The semiconductor integrated circuit device of claim 4, wherein the first recessed portion is positioned at the first side of the main gate, the main gate further comprises a second recessed portion formed at the second side of the main gate across from the first recessed portion, and a second distance is formed between the main gate and the bit line contact.

6. A semiconductor integrated circuit device comprising:
an isolation region;
a plurality of active regions defined by the isolation region, each of the active regions including a first junction region electrically connected with a storage node contact and a second junction region electrically connected with a bit line contact;
a plurality of word lines, each of the plurality of word lines including a first gate and a second gate, the first gate positioned between the first junction region and the second junction region and the second gate positioned on the isolation region,
wherein the first gate comprises a first recessed portion positioned at a first sidewall of the first gate adjacent to the storage node contact and a second recessed portion across from the first recessed portion and positioned at a second sidewall of the first gate adjacent to the bit line contact.

7. The semiconductor integrated circuit device of claim 6, wherein the first sidewall of the first gate is configured to surround the storage node contact along at least one of horizontal, vertical and diagonal directions within a first distance.

8. The semiconductor integrated circuit device of claim 7, wherein the first distance is a maximum distance for inducing charge coupling between the first gate and the storage node contact.

9. The semiconductor integrated circuit device of claim 6, wherein the second sidewall of the first gate including the second recessed portion is spaced apart from the bit line contact by a second distance.

10. The semiconductor integrated circuit device of claim 9, wherein the second distance is a minimum distance for preventing charge coupling.

11. The semiconductor integrated circuit device of claim 6, wherein the second gate comprises a first portion facing adjacent active region adjacent to the word line and a second portion facing another word line adjacent to the word line.

12. The semiconductor integrated circuit device of claim 11, wherein the first portion of the second gate has a width different from a width of the second portion of the second gate.

13. The semiconductor integrated circuit device of claim 11, wherein the second gate includes a third recessed portion, the third recessed portion is formed at a sidewall of the first portion which faces to a second junction region of the adjacent active region, and a third distance is maintained between the first portion of the second gate and the second junction electrically connected to the storage node contact in all directions by the third recessed portion.

14. The semiconductor integrated circuit device of claim 13, wherein the third distance is a minimum distance for preventing charge coupling.

15. The semiconductor integrated circuit device of claim 11, wherein a width of the first gate is substantially the same as a width of the first portion of the second gate, and the width of the first portion of the second gate is narrower than a width of the second portion of the second gate.

16. A semiconductor integrated circuit device comprising:
a plurality of word lines parallelly extended on a plurality of active regions; and
an isolation region configured to define the active regions,
wherein each of the word lines comprises a main gate passing through the active regions and a pass gate passing into the isolation region, and
wherein a width of the main gate and a width of a first portion in the pass gate are narrower than a width of a word line and a second portion extended from the first portion of the pass gate has a width substantially the same as the width of the word line.

17. A semiconductor integrated circuit device comprising:
a substrate;
an isolation region formed in the substrate;
a plurality of active regions defined by the isolation region, each of the active regions including a storage node contact and a bit line contact formed on the substrate;
a plurality of word lines a) formed on the substrate, b) intersecting the plurality of active regions at an acute angle, and c) including a main gate configured to gate a channel in an active region and a pass gate configured to transmit a word line signal, the main gate positioned between the storage node contact and the bit line contact, and the pass gate positioned away from the main gate and extending into the isolation region,
wherein
both the main gate and the pass gate have recessed portions reducing respective widths of the main gate and the pass gate in selected portions of the main gate and the pass gate,
the recessed portions on the main gate forming a structure which partially surrounds the storage node contact and thereby enhance charge coupling from the main gate to the storage node contact, and
the recessed portions on the pass gate further separate the pass gate from an adjacent storage node contact on an adjacent word line and thereby reduce charge coupling from the pass gate to the adjacent storage node contact.
